(19) United States
(12) Patent Application Publication
(10) Pub. No.: US 2023/0254963 A1
(43) Pub. Date: Aug. 10, 2023

(54) SPINNING DISK PLASMA REACTOR FOR TREATMENT OF WATER

(71) Applicants: Selma Mededovic-Thagard, Potsdam, NY (US); Thomas M. Holsen, Potsdam, NY (US)

(72) Inventors: Selma Mededovic-Thagard, Potsdam, NY (US); Thomas M. Holsen, Potsdam, NY (US)

(73) Assignee: Clarkson University, Potsdam, NY (US)

(21) Appl. No.: 17/669,087

(22) Filed: Feb. 10, 2022

(51) Int. Cl. H05H 1/24; H01J 37/32

(52) U.S. Cl. CPC H05H 1/2443; H05H 1/2418; H01J 37/32348; H01J 37/32211

(57) ABSTRACT

Provided is a spinning disc with plasma discharges for the treatment of liquid. In one configuration, plasma is introduced to the surface of a liquid by a point-plane discharge, dielectric barrier discharge or as a plasma jet. This liquid exists as a thin film on the surface of the spinning disc. The thin liquid layer, as well as the enhanced mixing provided by the spinning disc, allow the plasma generated radicals to more easily interact with the contaminant.

### CROSS-REFERENCE TO RELATED APPLICATION

This application claims priority to U.S. Provisional Patent Application Ser. No. 63/147,773, filed on Feb. 10, 2021 and entitled “A Spinning Disk Plasma Reactor for Treatment of Water,” the entire disclosure of which is incorporated herein by reference.

### FIELD OF THE INVENTION

The present disclosure is directed generally to methods and systems for treating liquid, and more specifically, for treating liquid using a plasma-based process.

### BACKGROUND

Removal of dissolved organic compounds from drinking water, wastewater, and contaminated groundwater is a standard process in water treatment. Conventionally, methods for the removal of these organics include physical removal or the addition of chemical oxidants. These physical processes can be energy intensive, and the addition of chemicals can lead to undesirable byproducts.

Plasma-based process intensification is considered as a promising technology in advanced oxidation processes for the wastewater treatment. Gas-phase electrical discharge plasmas generated upon the surface of water have been shown to degrade dissolved surfactant-like organic compounds with high energy efficiency and no chemical additives because they can be transported by bubbles to the liquid surface where the plasma generated radicals are produced. However, degradation of non-surfactant compounds is slow as these chemicals tend to remain in the bulk liquid phase and are not exposed to the plasma generated radicals.

Accordingly, there is a need in the art for a reactor that more efficiently degrades non-surfactant compounds.

### SUMMARY

The present disclosure is directed to a spinning disk plasma reactor for treatment of water.

A plasma spinning disc reactor (PSDR) has the ability to create a thin film of liquid across the surface of a disc. When liquid is supplied to the center of a rotating surface, the liquid flows to the surface's edge as a film. Initially, the liquid is accelerated tangentially by the shear stress at the liquid/disc interface. As the liquid reaches its angular velocity, it moves outward as a thinning film under centrifugal force. This thinning will allow the plasma-generated radicals to penetrate the entirety of the liquid layer. Furthermore, the stresses imposed on the liquid layer as it spreads across the disc lead to mixing of the contaminant and the radicals.

According to an aspect is an electrical discharge plasma reactor system for treating a liquid, the reactor system comprising a reactor chamber configured to contain the liquid and a gas; a discharge electrode disposed within the reactor chamber, wherein the discharge electrode is disposed within the gas; an opposing electrode disposed within the reactor chamber in spaced relation to the discharge electrode and and in alignment with the liquid; at least one disc disposed within the reactor chamber, wherein the disc is configured to be rotated and induce a thin film of liquid in a plasma-contact region; and a power supply connected to one of the discharge electrode and the opposing electrode, the power supply configured to induce the discharge electrode and the opposing electrode to generate plasma in the plasma-contact region.

According to an embodiment, the discharge electrode is disposed within the gas in any one of the following configurations: single or multiple points, plate with and without an attached dielectric and jet or a jet array.

According to an embodiment, the discharge electrode is disposed within the gas in any one of the following configurations: single or multiple points, plate with and without an attached dielectric and jet or a jet array.

According to an embodiment, the plasma generation occurs by point-to-plane discharge.

According to an embodiment, the plasma generation occurs by dielectric barrier discharge.

According to an embodiment, the plasma generation occurs by a plasma jet.

These and other aspects of the invention will be apparent from the embodiments described below.

### BRIEF DESCRIPTION OF THE DRAWINGS

The present invention will be more fully understood and appreciated by reading the following Detailed Description in conjunction with the accompanying drawings, in which:

FIG. 1 is a schematic representation of a point to plane configuration of a spinning disc reactor, in accordance with an embodiment.

FIG. 2 is a schematic representation of a dielectric barrier discharge configuration of a spinning disc reactor, in accordance with an embodiment.

### DETAILED DESCRIPTION OF EMBODIMENTS

The present disclosure describes a spinning disk plasma reactor for treatment of water.

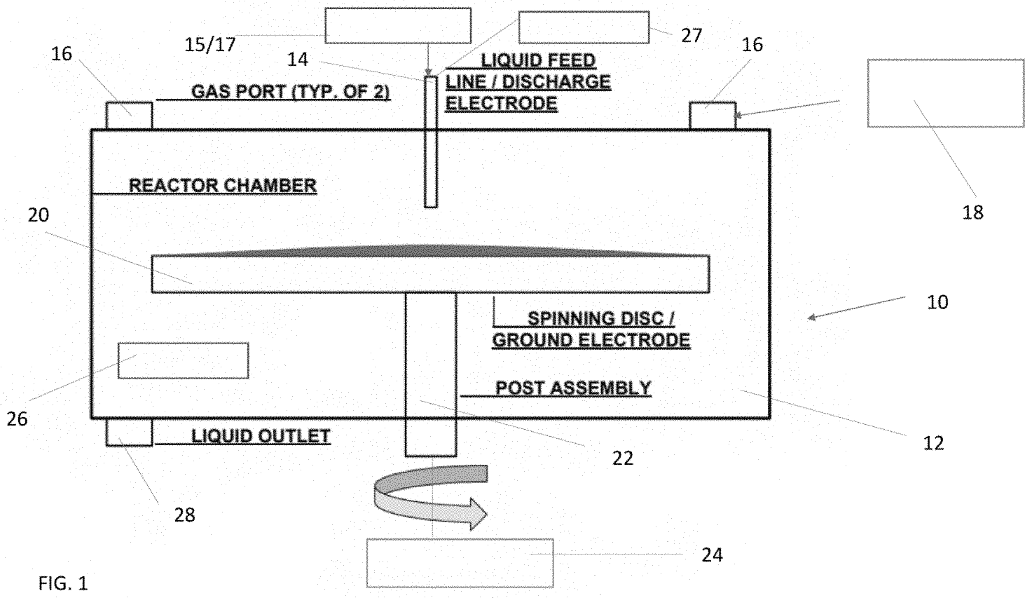

Referring to FIG. 1, in one embodiment, is a spinning disc reactor designated generally by reference numeral 10 is shown. Reactor 10 comprises a reactor chamber 12 where the treatment of water is to take place. An inlet pipe 14 provides the conduit into chamber 12 for water to be treated 15 (the water to be treated is pumped or otherwise moved from its source through pipe 14). Positioned at the top of the reactor 12 are one or more gas ports 16 connected a gas source 18, such as air, oxygen, argon and helium (and combinations thereof), which is introduced into the reactor chamber 12. Contained within the reactor chamber 12 beneath the exit of the inlet pipe 14 is a disc/electrode 20 that mounted to the top of a post 22 that passes through a sealed opening in the bottom of the reactor chamber 12 and is, in turn, attached to a motor 24 to impart rotary/spinning motion to the post and disc 20. Inlet pipe 14 further serves as a discharge electrode 17 to emit a charging current and provide voltage to generate the electric field between the discharge electrode and collecting disc/electrode 20 and create plasma therebetween. Disc 20 can serve as a high voltage electrode 24 (or be a grounded electrode) with a point-plane electrical discharge generating filamentary plasma in its proximity via a plasma generator 26. A power supply 27 connects to the discharge electrode 17 (or could connect to disc/electrode 20); power can be either AC or DC (pulsed and continuous, voltages ranging from 0 to 100 kV and currents ranging from a few Amperes to over several thousand Amperes) and is configured to induce the discharge electrode and the opposing electrode to generate plasma in the plasma-contact region between the two electrodes.

As the disc 20 spins about the axis of the post 22, it has the ability to create a thin film of liquid across the surface of the disc. The water to be treated that is supplied towards the center of a rotating surface causes the liquid to flow to the surface's edge as a film. Initially, the liquid is accelerated tangentially by the shear stress at the liquid/disc interface. As the liquid reaches its angular velocity, it moves outward as a thinning film under centrifugal force. This thinning will allow the plasma-generated radicals to penetrate the entirety of the liquid layer. Furthermore, the stresses imposed on the liquid layer as it spreads across the disc lead to mixing of the contaminant and the radicals. The treated water then exits chamber 12 through an exit pipe 28

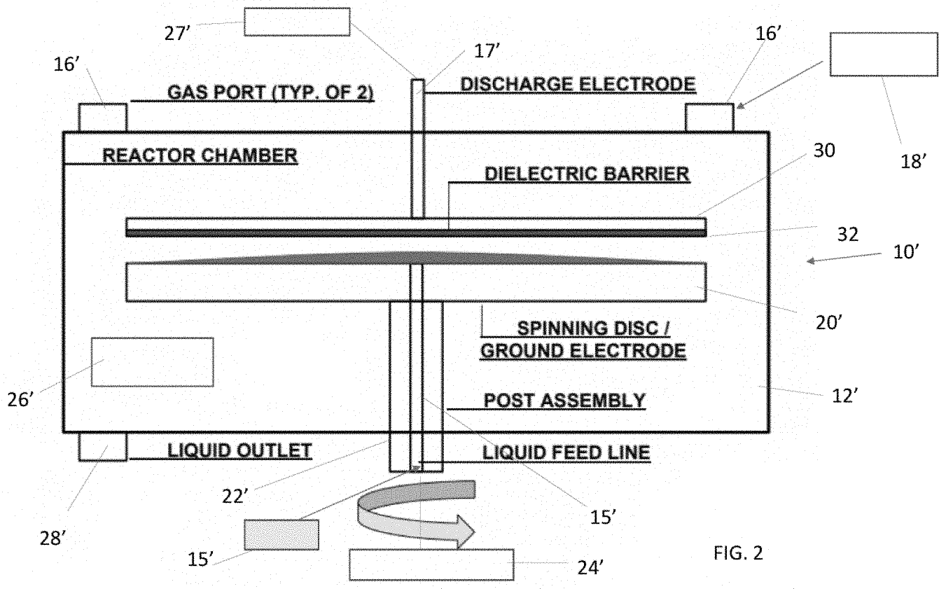

Referring to FIG. 2, a spinning disc reactor designated generally by reference numeral 10′ is shown. Reactor 10′ has the same elements as reactor 10 with those same elements designated with the same reference numeral with a ‘ symbol added, as well as additional elements described hereinafter. The inlet pipe 15’ for introducing the water to be treated into reactor chamber 12′ is positioned at the bottom of chamber 12′ extending through the post assembly 22′ that connects to rotating disc 20′. Reactor 10′ includes a dielectric barrier discharge that generates a plasma between two plates, one of them being the rotating disc 20′ and the other a metal plate 30 on which a dielectric material 32 has been affixed. A discharge electrode 17′ is positioned at the top of chamber 12′ and extends to metal plate 30 to emit a charging current and provide voltage to generate the electric field needed to generate the plasma. Power supply 27′ provides the power in the same manner as power supply 27.

It should be noted that discharge electrode 17, 17′ can be configured as single or multiple points, plate with and without an attached dielectric and jet or a jet array placed into contact with the disc 20/20′. Also, either of the electrodes can be grounded or serve as the high voltage electrode. In addition, there may be one or more discs 20/20′ included. There may also be multiple discharge points and their arrangement may be random, spiral or diagonal. Disc 20/20′ may also be covered with a non-conducting material to force the plasma to travel across the disk. The disc 20/20′ may be porous, solid and flat with varying degrees of roughness, brush-like, and may contain imprinted patterns.

While various embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings is/are used. Those skilled in the art will recognize, or be able to ascertain using no more than routine experimentation, many equivalents to the specific embodiments described herein. It is, therefore, to be understood that the foregoing embodiments are presented by way of example only and that, within the scope of the appended claims and equivalents thereto, embodiments may be practiced otherwise than as specifically described and claimed. Embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

The above-described embodiments of the described subject matter can be implemented in any of numerous ways. For example, some embodiments may be implemented using hardware, software or a combination thereof. When any aspect of an embodiment is implemented at least in part in software, the software code can be executed on any suitable processor or collection of processors, whether provided in a single device or computer or distributed among multiple devices/computers.

What is claimed is:

1. An electrical discharge plasma reactor system for treating a liquid, the reactor system comprising:
a. a reactor chamber configured to contain the liquid and a gas;
b. a discharge electrode disposed within the reactor chamber, wherein the discharge electrode is disposed within the gas;
c. an opposing electrode disposed within the reactor chamber in spaced relation to the discharge electrode and in alignment with the liquid;
d. at least one disc disposed within the reactor chamber, wherein the disc is configured to be rotated and induce a thin film of liquid in a plasma-contact region; and
e. a power supply connected to one of the discharge electrode and the opposing electrode, the power supply configured to induce the discharge electrode and the opposing electrode to generate plasma in the plasma-contact region.

2. The electrical discharge plasma reactor system according to claim 1, wherein the discharge electrode is disposed within the gas in any one of the following configurations: single or multiple points, plate with and without an attached dielectric and jet or a jet array.

3. The electrical discharge plasma reactor system according to claim 1, wherein the plasma generation occurs by point-to-plane discharge.

4. The electrical discharge plasma reactor system according to claim 1, wherein the plasma generation occurs by dielectric barrier discharge.

5. The electrical discharge plasma reactor system according to claim 1, wherein the plasma generation occurs by a plasma jet.
